(19) United States
(12) Patent Application Publication
(10) Pub. No.: US 2005/0026342 A1
(43) Pub. Date: Feb. 3, 2005

(54) Semiconductor device having improved short channel effects, and method of forming thereof

(76) Inventors: Ka-Hing Fung, Hsin-Chu (TW); Yin-Ping Wang, Hsin-Chu (TW); Huan-Tsung Huang, Hsin-Chu (TW)

Correspondence Address: SLATER & MATSIL, L.L.P., 17950 PRESTON ROAD, SUITE 1000, DALLAS, TX, 75252, US

(21) Appl. No.: 10/628,747

(22) Filed: Jul. 28, 2003

(51) Int. Cl. H01L 21/336; H01L 21/8234

(52) U.S. Cl. 438/197; 438/305; 438/306

(57) ABSTRACT

Semiconductor device having improved short channel effects and method of forming thereof. One method includes forming a gate oxide over a substrate and a gate electrode over the gate oxide, and implanting impurities into the substrate using the gate electrode as an implant mask to form a lightly-doped region in the substrate. The method includes depositing second spacer material adjacent to the gate electrode, forming a first spacer on the second spacer material, and implanting impurities into the substrate and through a portion of the lightly-doped region using the first spacer as an implant mask to form a first junction region in the substrate. The method includes removing the first spacer, etching the second spacer material to form a second spacer adjacent the gate electrode, and implanting impurities into the substrate using the second spacer as an implant mask to form a second junction region in the substrate.

### TECHNICAL FIELD

This disclosure relates, in general, to semiconductor processes, and, more specifically, to methods of manufacturing a semiconductor device having improved junction capacitance, junction impedance, and other short channel effects, and semiconductor devices resulting from the methods.

### BACKGROUND

The manufacture of integrated circuits on semiconductor wafers has continued to allow electrical devices to become more compact, yet with improved performance and greater capabilities. As a result, manufacturers are constantly improving on the manufacturing techniques and processes for the semiconductor devices forming these integrated circuits. In particular, silicon-on-insulator (SOI) technology is becoming an increasingly important field in the manufacture of integrated circuits. SOI technology deals with forming semiconductor devices, such as transistors, in a layer of semiconductor material overlying an insulating layer. The insulating layer is formed on an underlying substrate of a semiconductor wafer, and electrically isolates the devices from other areas and devices of the integrated circuit. Electrical interconnects are then formed throughout the various layers of the wafer to interconnect the different devices to form the circuit.

Typically, such transistors include junction regions implanted into the semiconductor material on either side of a gate structure, and usually include source/drain regions and lightly-doped drain (LDD) regions. The gate structure is formed on the surface of the semiconductor material, over a channel generally defined between the junction regions, which are typically formed deep into the semiconductor material and reach the insulating layer. To manufacture such devices, conventional processes form spacers adjacent the gate structure, and then perform an implant to form heavy-doped deep junction regions alongside the channel, yet still relatively far away from it. The spacers are then removed and more spacers are formed, yet smaller in width, to dope the source/drain regions closer to the channel, resulting in graded junctions on either side of the channel. Throughout this process, various levels of doping are usually used to specifically engineer the junction capacitance (Cj) in an attempt to optimize device performance.

Eventually, those spacers are removed and even smaller spacers are used for another implant to form the LDD regions of the device and to define the final length of the channel. Alternatively, no spacers are used at this stage of the process, and the gate structure is used as a mask for the LDD implant. By starting with larger spacers and then employing smaller spacers, and by lessening the doping profile of the corresponding implants, the graded junctions formed by the deep junctions, the source/drain regions, and the LDD regions are carefully formed in an attempt to optimize junction impedance (Xj) and other short channel effects of the device.

Unfortunately, changing from wider spacers to narrower spacers during the manufacturing process requires a corresponding change in doping profile (e.g., lowering the dopant concentration at each implant), as mentioned above, often resulting in a penalty in the final Cj of the device. In addition, the etchants typically employed to remove spacers during the manufacturing process, so that the LDD regions may eventually be formed, often damage the surface of the semiconductor substrate. Such damage becomes even more critical to device design and performance as device size decreases, such as in ultra-thin SOI manufacturing. Moreover, with each subsequent removal of the various spacers used to form graded junctions, spacer residue, usually oxide, may build up on the surface of the semiconductor substrate. As a result, attempting to diffuse dopant through a thick oxide build-up increases the difficulty of performing a shallow implant to form the shallow regions, i.e., the LDD regions, of the device. Accordingly, what is needed in the art is a method for manufacturing semiconductor devices that does not suffer from the deficiencies of conventional techniques, and that may be employed with ultra-thin manufacturing techniques, such as ultra-thin SOI manufacturing.

### SUMMARY OF THE INVENTION

To address the above-discussed deficiencies of the prior art, this disclosure provides, in one aspect, a method of manufacturing a semiconductor device. In one embodiment, the method includes forming a gate oxide over a substrate and a gate electrode over the gate oxide. The method further includes implanting impurities into the substrate using the gate electrode as an implant mask to form a lightly-doped region in the substrate. In addition, the method includes depositing second spacer material adjacent to the gate electrode, and then forming a first spacer on the second spacer material. In this embodiment, the method still further includes implanting impurities into the substrate and through a portion of the lightly-doped region using the first spacer as an implant mask to form a first junction region in the substrate. Then, the method includes removing the first spacer, and etching the second spacer material to form a second spacer adjacent the gate electrode. Next, the method includes implanting impurities into the substrate using the second spacer as an implant mask to form a second junction region in the substrate.

In another aspect, the present invention provides another embodiment of a method of manufacturing a semiconductor device. In this embodiment, the method includes forming a gate oxide over a substrate and a gate electrode having a gate width of less than 0.13 micron over the gate oxide. The method then includes implanting impurities into select regions of the substrate using the gate electrode as an implant mask to form a lightly-doped region in the substrate having a channel region extending therebetween beneath the gate oxide, the channel region having a channel length of less than about 0.13 μm. Furthermore, the method includes depositing a bottom layer over the gate electrode and the substrate, and an upper layer over the bottom layer, and then removing portions of the upper layer to form a first spacer adjacent the gate electrode. In this embodiment, the method then includes implanting impurities through a portion of the lightly doped region using the first spacer as an implant mask to form a first junction region in the substrate, and then removing the first spacer. The method still further includes removing portions of the bottom layer to form a second spacer adjacent the gate electrode, and then implanting impurities through a portion of the lightly doped region and into the substrate using the second spacer as an implant mask to form a second junction region in the substrate.

In yet another aspect, the present invention provides a semiconductor device. In one embodiment, the semiconductor device comprises a gate structure formed over a semiconductor region, and a lightly doped source/drain region formed in the semiconductor region to a first depth, where the lightly doped source/drain region is substantially aligned with a sidewall of the gate structure. The device further includes a sidewall spacer formed along a sidewall of the gate structure, and a heavily doped source/drain region formed in the semiconductor region to a second depth deeper than the first depth, where the heavily doped source/drain region is substantially aligned with an outer edge of the sidewall spacer. In this embodiment, the device further includes a deep source/drain region formed in the semiconductor region to a third depth deeper than the second depth, where the deep source/drain region is spaced a lateral distance from the outer edge of the sidewall spacer.

The foregoing has outlined preferred and alternative features of the disclosed process so that those skilled in the art may better understand the detailed description that follows. Additional features of the invention will be described hereinafter that form the subject of the attached claims. Those skilled in the art should appreciate that they can readily use the disclosed conception and specific embodiments as a basis for designing or modifying other structures for carrying out the same purposes. Those skilled in the art should also realize that such equivalent constructions do not depart from the spirit and scope of the issued claims and their equivalents.

### BRIEF DESCRIPTION OF THE DRAWINGS

For a more complete understanding of embodiments of the present invention, reference is now made to the following detailed description taken in conjunction with the accompanying drawings. It is emphasized that various features may not be drawn to scale. In fact, the dimensions of various features may be arbitrarily increased or reduced for clarity of discussion. In addition, it is emphasized that some components may not be illustrated for clarity of discussion. Reference is now made to the following descriptions taken in conjunction with the accompanying drawings, in which:

FIG. 1 illustrates a semiconductor device constructed according to one embodiment of a process disclosed herein during early stages of the process;

FIG. 2 illustrates the semiconductor device of FIG. 1 during a later stage in the disclosed manufacturing process;

FIG. 3 illustrates the semiconductor device discussed above during another implant performed during the manufacturing process;

FIG. 4 illustrates the semiconductor device of FIGS. 1-3 deeper into the manufacturing process;

FIG. 5 illustrates the semiconductor device during an optional stage of the manufacturing process;

FIG. 6 illustrates the semiconductor device discussed above at the latter stage of manufacture; and

FIG. 7 illustrates a sectional view of an integrated circuit incorporating the manufacturing process disclosed herein.

### DETAILED DESCRIPTION OF ILLUSTRATIVE EMBODIMENTS

In the following discussion, numerous specific details are set forth to provide a thorough understanding of the disclosure. However, those skilled in the art will appreciate that the techniques herein may be practiced without such specific details. In other instances, well-known elements have been illustrated in schematic or block diagram form in order not to obscure the disclosure in unnecessary detail. Additionally, some details have been omitted inasmuch as such details are not considered necessary to obtain a complete understanding of the disclosure, and are considered to be within the understanding of persons of ordinary skill in the relevant field of art.

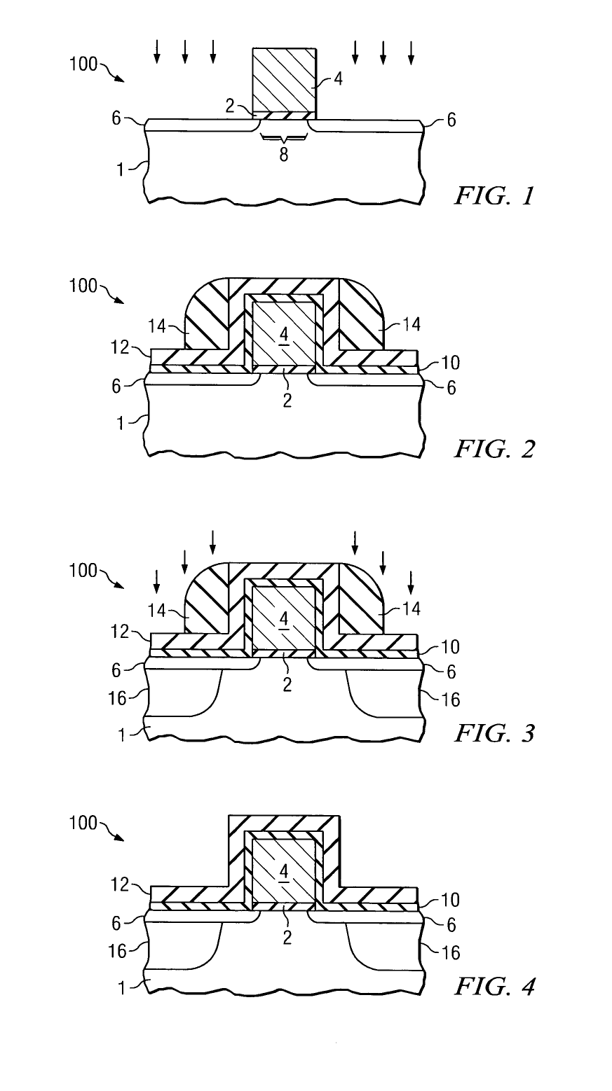

Referring initially to FIG. 1, illustrated is a semiconductor device 100 constructed according to one embodiment of a process disclosed herein. The semiconductor device 100 is illustrated during an initial stage of the novel manufacturing process. In one embodiment, the semiconductor device 100 will be a metal oxide semiconductor field effect transistor (MOSFET). However, the disclosed manufacturing process is not limited to constructing a MOSFET, and any useful semiconductor device may be constructed.

As shown, a gate oxide 2 has been formed over the surface of a substrate. In an advantageous embodiment, the substrate 1 is a semiconductor material, and in a more specific embodiment, the substrate 1 is silicon-on-insulator (SOI) constructed according to conventional techniques. Of course, the substrate 1 may be constructed of any beneficial material useful in constructing semiconductor devices. Moreover, the gate oxide 2 is preferably a low temperature oxide formed using conventional techniques, such as chemical vapor deposition (CVD), although other deposition techniques are within the scope of the present invention.

Also as illustrated in FIG. 1, a gate electrode 4 is formed over the gate oxide 2. In one embodiment, the gate electrode 4 is formed using a blanket deposit of an appropriate material, which is then etched to form the gate electrode 4. In a specific embodiment, the gate electrode 4 is formed from polysilicon, however any appropriate material may be employed in the manufacture of the semiconductor device 100. Furthermore, the gate electrode 4 may also be formed using any appropriate technique, either now existing or later developed.

During the next step in the process, an implant is performed over the gate electrode 4 and into the substrate 1. The implant results in lightly-doped regions (LDDs) 6 formed beneath the surface of the substrate 1. More specifically, the implant is performed using the gate electrode 4 as a mask, masking off an area of the substrate 1 intended to be substantially protected from the implant during the implantation process. As illustrated, although the gate electrode 4 serves as a mask during the implanting of the LDDs 6, the dopant implanted into the substrate 1 may still seep slightly under the gate oxide 2 and gate electrode 4, which is often desirable in the manufacturing of semiconductor devices. In other words, although the dopant is implanted to be aligned to the implant mask, subsequent diffusion will cause migration of the dopant outside of the mask pattern. In the resulting structure, the dopant profile will nonetheless be substantially aligned to the implant masks. To perform the implant and form the LDDs 6, a dopant concentration in the range of about 1×10¹⁸ cm⁻³ to about 1×10²⁰ cm⁻³ may be employed. Those who are skilled in the pertinent field of art will understand the various process parameters that may be employed when performing such implants, and any such parameters may be employed with the disclosed process.

After the LDDs 6 have been formed in the substrate 1, a channel region 8 is defined between the LDDs 6 and directly beneath the gate oxide 2. Specifically, the dopant selected for implanting and forming the LDDs 6 is selected to provide a polarity opposite to the polarity of the tub of the substrate 1 in which the LDDs 6 are formed. As a result, the channel region 8 is nonconductive between the LDDs 6 until a charge is placed across the gate electrode 4. By activating the gate electrode 4, an inversion will occur in the channel region 8, inverting its polarity to that of the LDDs 6 to allow current to flow therethrough. For example, the dopant may be comprised substantially of arsenic or phosphorous if the semiconductor device 100 is intended to be an N-channel device, or substantially of boron if the semiconductor device 100 is intended to be a P-channel device. As with the process parameters discussed above, those who are skilled in the pertinent field of art will understand the various types of dopants that may be employed, and the resulting polarities associated with each, when performing such implants, and any such parameters may be employed with the disclosed process.

Turning now to FIG. 2, illustrated is the semiconductor device 100 of FIG. 1 during a later stage in the disclosed manufacturing process. At this point in the process, an oxide layer 10 has been formed over the gate electrode 4 and the surface of the substrate 1. In an alternative embodiment, the oxide layer 10 may be formed before the implantation that forms the LDDs 6; however, the disclosed process is not limited to either embodiment. In a more specific embodiment, the oxide layer 10 is a silicon oxide, such as (SiO₂), but any type of oxide may be employed. As with the gate oxide 2, the oxide layer 10 may be formed using conventional techniques, such as a CVD process.

After the oxide layer 10 is formed, a nitride layer 12 is formed over the oxide layer 10. The nitride layer 12 may be silicon nitride, but other nitride-based materials may also be employed. Also, the nitride layer 12 may be formed using techniques, such as a CVD process, or any other appropriate technique. Once the nitride layer 12 has been formed, another oxide layer is deposited over it. This new oxide layer is then etched to form oxide spacers 14 over the nitride layer 12 and adjacent the gate electrode 4. Also, the oxide spacers 14 are formed over portions of the LDDs 6 that are closest to the gate electrode 4 and gate oxide 2.

The above paragraphs describe the formation of an oxide-nitride-oxide (ONO) spacer structure. Alternatively, spacers formed solely of oxide or some other dielectric material, or combination of dielectric materials, will be apparent to one of ordinary skill in the art based upon the teachings provided herein.

Looking now at FIG. 3, illustrated is the semiconductor device 100 discussed above during another implant performed during the manufacturing process. More specifically, the implant is performed over the oxide spacers 14 such that the oxide spacers 14 are used as a mask during the implant. The implanted dopant passes through the nitride layer 12 and the oxide layer 10, and into the substrate 1. In an exemplary embodiment, this implant is performed using a dopant similar to the dopant employed to form the LDDs 6, but typically in a higher (higher =>lower) concentration, and results in the formation of deep junction regions 16 in the substrate 1. In one example, a dopant concentration in the range of about 1×10¹⁷ cm⁻³ to about 1×10²⁰ cm⁻³ may be employed and at higher implant energies.

As with the implanting that formed the LDDs 6, the dopant in this implant also has some lateral diffusion, this time under a portion of the oxide spacers 14. However, as illustrated, any such diffusion of the dopant when forming the deep junction regions 16 does not reach close to the channel region 8 defined by the ends of the LDDs 6. As a result, the tub in the substrate 1 maintains a graded dopant concentration when moving from the channel region 8 to either side of the tub. Those who are skilled in the art understand the importance of carefully engineering a graded channel/tub within a semiconductor device, such as the device 100 in FIG. 3, in order to optimize the operation of the device.

Referring now to FIG. 4, illustrated is the semiconductor device 100 of FIGS. 1-3 deeper into the manufacturing process. As is shown, once the deep junction regions 16 are formed in the substrate 1, the oxide spacers 14 are removed from the device 100. To remove the oxide spacers 14, a dry etch may be employed, or any other appropriate technique. In addition, since a nitride layer 12 has been employed under the oxide spacers 14, etch selectivity (e.g., endpoint detection) is easier, allowing the etch process to stop right at the nitride layer 12 without removing substantial portions of it, by choosing an etchant that etches silicon but not nitride.

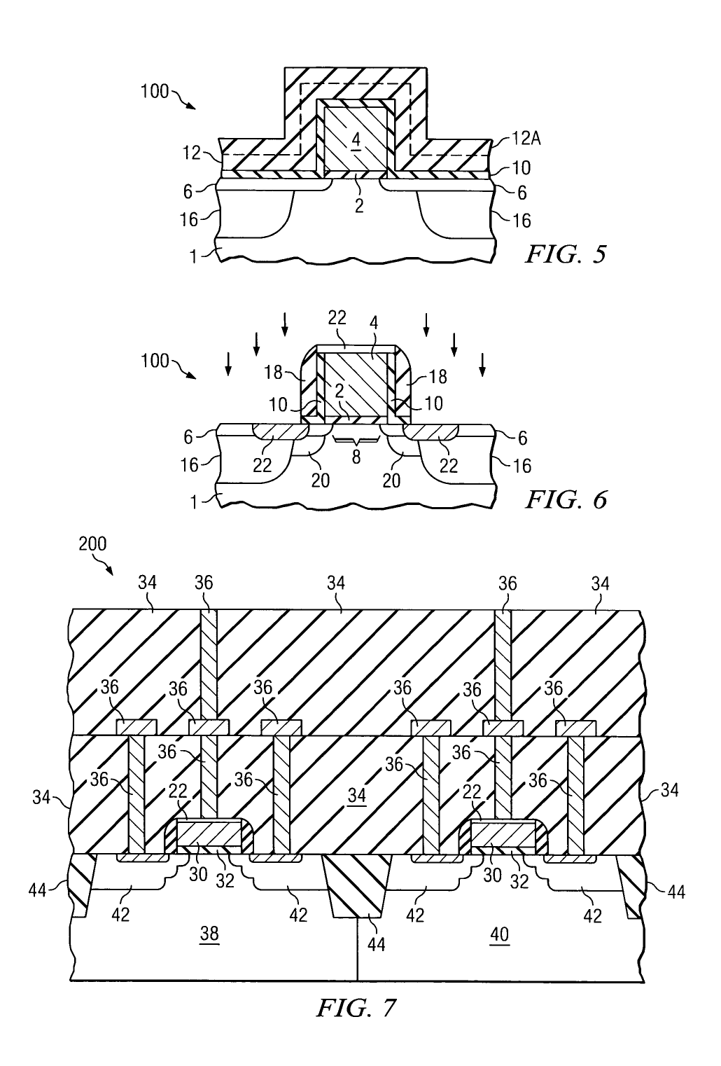

Turning now to FIG. 5, illustrated is the semiconductor device 100 during an optional stage of the manufacturing process. Once the oxide spacers 14 are removed, as discussed above, the nitride layer 12 is left exposed. In the embodiment shown in FIG. 5, an additional nitride layer 12A may be deposited over the original nitride layer 12. This may be done to add thickness to the nitride layer 12, if desired, to adjust the width of spacers to be formed from the nitride later in the process. As before, any technique, such as a CVD technique, may be employed to add the additional nitride layer 12A.

Looking now at FIG. 6, illustrated is the semiconductor device 100 discussed above, at the latter stage of manufacture. At this point in the process, the nitride layer 12, as well as the additional nitride layer 12A if it has been formed, is etched to form nitride spacers 18 adjacent the gate electrode 4. An anisotropic dry etch, or other appropriate technique, may be employed. Another implant may then be performed, using the nitride spacers 18 as a mask for the implanted dopant. As is shown in the illustrated embodiment, the nitride spacers 18 have a width less than that of the oxide spacers 14 employed during the implantation of the deep junction region 16. As a result, the implant diffuses into a different region of the substrate 1, forming the source/drain regions 20. It will be noted that the term source/drain region will refer to a source region, a drain region, or both a source and a drain region, depending upon the context in which the term is used. It is generally intended that the term will be given its broadest interpretation for the context.

In an exemplary embodiment, the implant used to form the source/drain regions 20 is performed using a dopant similar to the dopant employed to form the LDDs 6 and the deep junction regions 16. In a more specific embodiment, a dopant concentration in the range of about 1×10¹⁸ cm⁻³ to about 1×10²¹ cm⁻³ may be employed. Of course, other process parameters and dopants may also be employed to form the source/drain regions 20.

In an alternative embodiment, additional nitride to form the nitride layer 12A, and thus a thicker overall nitride layer, may be deposited such that the nitride spacers 18 have a width larger than the width of the oxide spacers 14. In such an embodiment, the nitride spacers 18 are used as an implant mask to form the deep junction regions 16, while the oxide spacers 14, now having a smaller width than the nitride spacers 18, are used as an implant mask to form the source/drain regions 20.

Next, portions of the oxide layer 10 over the source and drain regions 20 and over the gate electrode 4 are removed, for example, using conventional etching techniques. Then, self-aligned silicide contacts 22 may be formed over the source and drain regions 20 using the nitride spacers 18 as a mask for the silicide formation. In addition, a silicide contact 22 may also be formed over the gate electrode 4, as illustrated. The silicide contacts 22 may be incorporated into the process to provide a better connection between the source/drain regions 20 and gate electrode 4 of the device 100 and metal interconnects (not illustrated) used to electrically connect those portions of the device into an operative circuit. Although not necessary to the practice of the disclosed process, the silicide contacts 22 may be formed by either directly depositing a silicide, such as titanium silicide or cobalt silicide or the like, or alternatively, by depositing a metal (e.g., titanium, tungsten, cobalt, nickel) and then forming the silicide in situ by the interaction of the metal and the underlying silicon.

With the width of the nitride spacers 18 less than that of the oxide spacers 14, but laterally extending further than the gate electrode 4, the dopant used to form the source/drain regions 20 diffuses in closer to the channel region 8 than did the dopant used to form the deep junction regions 16. As a result, the location of the source/drain regions 20 is closer to the channel region 8 than the deep junction regions 16, but not as close as the location of the LDDs 6. Also, the dopant concentration results in a graded layout between the resulting junction regions. After a final thermal cycle, the dopants in the various regions of this graded junction then diffuse into their final locations, with respect to the channel region 8. It should be noted that the disclosed process described above is not limited to the specific steps set forth therein. Thus, a greater or lesser number of steps may be employed, and some steps, such as specific thermal cycles, have been omitted for clarity of discussion since they are not deemed necessary to understand or practice the process. However, those who are skilled in the art understand that such additional steps may be added without deviating from the scope of the disclosed process. Additionally, steps having greater or lesser detail than those discussed herein may also be employed to advantage.

In an alternative embodiment, rather than forming the deep junction regions 16 before forming the source/drain regions 20, the process order may be altered by first forming the LDDs 6, then employing the techniques described above to form a spacer to serve as an implant mask for forming the source/drain regions 20. Then, the remaining portions of the above-described technique may be employed to form spacers to serve as an implant mask for the deep junction regions 16. Of course, the benefits provided by the principles disclosed herein may be realized by either embodiment.

By employing the disclosed process, the deep junction regions 16, source/drain regions 20 and the LDDs 6 form a graded junction structure adjacent the channel region 8 providing for improved junction capacitance (Cj) without degrading short channel effects (Cjb=>SCE). In addition, the novel process provides improved resistivity (i.e., junction impedance (Xj)) without degrading device drive current (Idsat−Ioff=>Idsat), resulting in further improved short channel effects in the semiconductor device 100. In one example, the Cj may be in the range of about 0.2 fF/um² to about 0.8 fF/um², and the resistivity may be in the range of about 100 ohm-μm to about 300 ohm-μm. Moreover, the widths of the spacers employed in the disclosed process may also be adjusted to fine-tune the Cj and Xj, as well as other short channel effects of the device 100 to any particular application. Adjusting the widths of the spacers also provides the opportunity to minimize the distance from the channel region 8 to the silicide contacts 22, improving overall device 100 performance, without the risk of leakage impairing device performance.

In addition, by forming the LDDs 6 early in the manufacturing process, spacer residue in the contact etch used in conventional techniques to remove disposable spacers may be reduced or even eliminated. More specifically, the hot phosphoric acid (H₃PO₄) typically used to remove spacers in conventional techniques often damages the silicon surface of the substrate, impacting device performance. Furthermore, the process disclosed herein may be employed to manufacture any type of semiconductor device, including use in ultra-thin SOI processing, while retaining the benefits discussed above. Also, by minimizing the spacer width, as discussed above, the novel process provides a large contact-etching window and avoids the spacer residue to increase the contact resistance.

It is believed that the above features of the present invention are particularly advantageous for transistor devices and integrated circuits having minimum feature sizes, such as gate widths of 0.13 μm, 90 nm, and below. This is because devices having such small features sizes, and hence such small gate lengths, are particularly vulnerable to short channel effects. The novel process and resulting structure of the present invention is particularly advantageous to overcome the short channel effects problems associated with the source/drain doping profiles in a manner that is compatible with and eliminates several of the problems associated with conventional manufacturing processes.

Turning finally to FIG. 7, illustrated is a sectional view of an integrated circuit (IC) 200 incorporating the manufacturing process disclosed herein. The IC 200 may include active devices, such as transistors, used to form CMOS devices, BiCMOS devices, bipolar devices, or other types of active devices. The IC 200 may further include passive devices, such as inductors or resistors, or it may also include optical devices or optoelectronic devices. Those skilled in the art are familiar with these various types of devices and their manufacture.

In the embodiment illustrated in FIG. 7, components of the IC 200 include transistors 30, having gate oxide layers 32, formed on a semiconductor wafer using the technique disclosed herein. The transistors 30 may be MOSFETs, however other types of transistors may also be manufactured. Interlevel dielectric layers 34 are then shown deposited over the transistors 30.

Interconnect structures 36 are formed in the interlevel dielectric layers 34 to form interconnections between the various components therein to form an operative integrated circuit. In addition, the interconnect structures 36 also connect the transistors 30 to other areas or components of the IC 200. Those skilled in the art understand how to connect these various devices together to form an operative integrated circuit. Also illustrated are conventionally formed tubs 38, 40 and shallow trench isolation (STI) regions 44, as well as the specific graded junction regions 42 manufactured according to the principles disclosed above.

Of course, use of the disclosed process is not limited to the manufacture of the particular components in the IC 200 illustrated in FIG. 7. In fact, the process is broad enough to encompass the manufacture of any type of component for use with an integrated circuit that would benefit from the advantages of the process discussed above. Beneficially, each time the method of the present invention is employed to form part or all of a semiconductor device in the IC 200, overall operation optimization may result due to the improved Cj and resistivity of the semiconductor devices, as well as other short channel effects.

Although the preferred embodiments have been described and illustrated by a symmetrical transistor in which the graded doped junctions are symmetric for both the source and drain, the present invention applies equally to an asymmetric device, such as, for instance, a device in which either the source or drain has a graded doped junction. For instance, in some embodiments, the source region might be formed with only an LDD and source region, whereas the drain is formed with an LDD, a deep junction, and a drain region. As such, one or more of the above described spacers might be formed on only one side of the gate electrode. One skilled in the art will recognize the many permutations of spacers and dopant profiles, both symmetrical and asymmetrical, can be obtained through routine experimentation based upon the teaching provided herein.

Although the present invention has been described in detail, those skilled in the art should understand that they can make various changes, substitutions and alterations herein without departing from the spirit and scope of the invention in its broadest form. The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method of manufacturing a semiconductor device, comprising:
forming a gate oxide over a substrate and a gate electrode over the gate oxide;
implanting impurities into the substrate using the gate electrode as an implant mask to form a lightly-doped region in the substrate;
depositing second spacer material adjacent the gate electrode;
forming a first spacer on the second spacer material;
implanting impurities into the substrate and through a portion of the lightly-doped region using the first spacer as an implant mask to form a first junction region in the substrate;
removing the first spacer;
etching the second spacer material to form a second spacer adjacent the gate electrode; and
implanting impurities into the substrate using the second spacer as an implant mask to form a second junction region in the substrate.

2. The method of claim 1, further including depositing additional second spacer material on the initially deposited second spacer material prior to etching the second spacer material.

3. The method of claim 1, wherein said first junction region is a deep junction region and said second junction region is a source/drain region.

4. The method of claim 1, wherein said first spacer comprises an oxide, and said second spacer material comprises a nitride.

5. The method of claim 1, wherein the second spacer has a width less than a width of the first spacer.

6. The method of claim 3, further including forming a silicide over the source/drain region.

7. The method of claim 1, wherein the substrate is a silicon-on-insulator substrate.

8. The method of claim 1, wherein the lightly-doped region has a dopant concentration in the range of about 1×10¹⁸ cm⁻³ to about 1×10²⁰ cm^{-3.}

9. The method of claim 1, wherein the first junction region has a dopant concentration in the range of about 1×10¹⁷ cm⁻³ to about 1×10²⁰ cm^{-3.}

10. The method of claim 1, wherein the second junction region has a dopant concentration in the range of about 1×10¹⁸ Cm⁻³ to about 1×10²¹ cm^{-3.}

11. A method of manufacturing a short channel semiconductor device, comprising:
forming a gate oxide over a substrate and a gate electrode having a gate width of less than 0.13 micron over the gate oxide;
implanting impurities into select regions of the substrate using the gate electrode as an implant mask to form a lightly-doped region in the substrate having a channel region extending therebetween beneath the gate oxide, the channel region having a channel length of less than 0.13 micron;
depositing a bottom layer over the gate electrode and the substrate, and an upper layer over the bottom layer;
removing portions of the upper layer to form a first spacer adjacent the gate electrode;
implanting impurities through a portion of the lightly doped region using the first spacer as an implant mask to form a first junction region in the substrate;
removing the first spacer;
removing portions of the bottom layer to form a second spacer adjacent the gate electrode; and
implanting impurities through a portion of the lightly doped region and into the substrate using the second spacer as an implant mask to form a second junction region in the substrate.

12. The method of claim 11, further including depositing additional bottom layer material on the initially deposited bottom layer prior to removing portions of the bottom layer to form the second spacer.

13. The method of claim 11, wherein said first junction region is a deep junction region and said second junction region is a source/drain region.

14. The method of claim 11, wherein depositing an upper layer comprises depositing an upper layer comprising an oxide, and wherein depositing a bottom layer comprises depositing a bottom layer comprising a nitride.

15. The method of claim 11, wherein removing portions of the bottom layer to form a second spacer further comprises removing portions of the bottom layer to form a second spacer having a width less than a width of the first spacer.

16. The method of claim 11, further including forming a silicide over the second junction region.

17. The method of claim 11, wherein the substrate is a silicon-on-insulator substrate.

18. The method of claim 11, further including:
forming a dielectric over the gate electrode and the second junction region;
forming a contact opening through said dielectric; and
forming an interconnect in said contact opening, the interconnect being electrically coupled to said second junction region.

19. The method of claim 11, wherein removing the first spacer comprises performing an etch step using hot H₃PO₄ acid.

20. The method of claim 11 further comprising forming a liner layer on the gate electrode and the substrate prior to depositing the bottom layer.

21. A semiconductor device comprising:
a gate structure formed over a semiconductor region;
a lightly doped source/drain region formed in the semiconductor region to a first depth, the lightly doped source/drain region substantially aligned with a sidewall of the gate structure;
a sidewall spacer formed along a sidewall of the gate structure;
a heavily doped source/drain region formed in the semiconductor region to a second depth deeper than the first depth, the heavily doped source/drain region substantially aligned with an outer edge of the sidewall spacer; and
a deep source/drain region formed in the semiconductor region to a third depth deeper than the second depth, the deep source/drain region spaced a lateral distance from the outer edge of the sidewall spacer.

22. The device of claim 21 and further comprising:
a second sidewall spacer formed along a second sidewall of the gate structure;
a second lightly doped source/drain region formed in the semiconductor region to the first depth, the second lightly doped source/drain region substantially aligned with a second sidewall of the gate structure;
a second heavily doped source/drain region formed in the semiconductor region to the second depth, the second heavily doped source/drain region substantially aligned with an outer edge of the second sidewall spacer; and
a second deep source/drain region formed in the semiconductor region to the third depth, the second deep source/drain region spaced a lateral distance from the outer edge of the second sidewall spacer.

23. The device of claim 21 wherein the lightly doped source/drain region, the heavily doped source/drain region, and the deep source/drain region are formed from impurities of the same conductivity type.

24. The device of claim 23 wherein the lightly doped source/drain region, the heavily doped source/drain region, and the deep source/drain region are formed from impurities of the same material.

25. The device of claim 21, further comprising a silicide region formed at the surface of the semiconductor region adjacent the outer edge of the sidewall spacer.
